(19) United States
(12) Patent Application Publication
(10) Pub. No.: US 2026/0031820 A1
(43) Pub. Date: Jan. 29, 2026

(54) Digital Frequency Divider, Voltage Supply, and Method for Operating and Testing a Voltage Supply

(71) Applicant: KNORR-BREMSE Systeme fuer Nutzfahrzeuge GmbH, Muenchen (DE)

(72) Inventors: Alexander RAMMERT, Muenchen (DE); Manuel Stegmann, Stuttgart (DE); Frank Scholl, Ingersheim (DE); Alexander Matt, Bruchsal (DE); Matthias Roth, Vaihingen an der Enz (DE); Guenter Herrmann, Stuttgart (DE); Emirhan Atmaca, Abstatt (DE); Christian Kaufmann, Schwieberdingen (DE); Dominick Willi Hermann Funk, Eisingen (DE)

(21) Appl. No.: 19/280,216

(22) Filed: Jul. 25, 2025

(30) Foreign Application Priority Data
Jul. 26, 2024 (DE) 10 2024 121 380.9

(51) Int. Cl. H03K 21/08

(52) U.S. Cl. CPC H03K 21/08

(57) ABSTRACT

A digital frequency divider for a voltage supply circuit of a controller is disclosed. The digital frequency divider has a counting unit which has a clock input for a clock signal, a reset input for a reset signal, and a plurality of outputs for division signals. The counting unit is designed to generate the division signals as a division of the clock signal by a power of 2. The digital frequency divider further has a first coupling circuit for coupling the division signals to form a coupling signal, wherein the coupling signal has a logical HIGH only if all coupled division signals have a logical HIGH; and a second coupling circuit which is designed to enter the coupling signal into the reset input of the counting unit.

### CROSS REFERENCE TO RELATED APPLICATION

This application claims priority under 35 U.S.C. § 119 from German Patent Application No. 10 2024 121 380.9, filed Jul. 26, 2024, the entire disclosure of which is herein expressly incorporated by reference.

### BACKGROUND AND SUMMARY

The present invention relates to a digital frequency divider, to a voltage supply for a controller and to a method for operating and testing a voltage supply circuit and, in particular, to a digital frequency divider with an adjustable division factor and test options.

Appropriate voltage supply chips (SVC) are often used to supply voltage to a controller (in particular to a microcontroller). Monitoring circuits (so-called watchdog circuits) are used to monitor the compatibility and the usability of both components. One option for monitoring is the so-called frequency window method, in which the monitoring circuit monitors a frequency emitted by the controller to ascertain whether it is in an acceptance window. If the frequency emitted by the controller is outside the acceptance window, the monitoring circuit can issue a warning signal in order, for example, to put the system into a safe state and to inform a user of the fault state. This is also utilized in this disclosure.

Particularly in the vehicle sector, there are many controllers for a wide variety of functions that can be combined with different voltage supply units. Typically, the components come from different manufacturers. This leads to the risk of compatibility problems, for example if a microcontroller and voltage supply chip that are not compatible with one another are interconnected. This can be detected by means of an acceptance window, as described above, for example. Conventional monitoring circuits, however, offer little flexibility in setting the acceptance window. This is due, in particular, to the internal frequency dividers used for this purpose.

Therefore, there is a need for frequency dividers that make it possible to set acceptance windows as flexibly as possible.

At least some of the above problems are overcome by a digital frequency divider, a voltage supply circuit, a controller and a method for operating and testing a voltage supply circuit, according to the independent claims. The dependent claims refer to further advantageous configurations of the subject matter of the independent claims.

The present invention relates to a digital frequency divider for a voltage supply circuit of a controller. The digital frequency divider comprises a counting unit which has a clock input for a clock signal, a reset input for a reset signal, and a plurality of outputs for division signals. The counting unit is designed to generate the division signals as a division of the clock signal by a power of 2. This is also referred to as a binary division ratio for the purposes of the present disclosure. The digital frequency divider also comprises a first coupling circuit and a second coupling circuit. The first coupling circuit couples the division signals to form a coupling signal in such a way that the coupling signal has a logical HIGH only if all the coupled division signals have a logical HIGH (otherwise the coupling signal is set to LOW; that is to say a logical AND operation). The second coupling circuit is designed to enter the coupling signal at least into the reset input of the counting unit.

If the frequency of the clock signal is f0, then the division signals have a frequency of f0/2ⁱ, where i is a natural number greater than zero. The coupling signal itself is also again a clock signal which is obtained by dividing the clock signal-however, by any (integer) division frequency f=f0/n, and n=3, 4, 5, 6, 7, . . . . The counting unit (counter or counting device) may be designed as a digital asynchronous counter or asynchronous dual counter and comprises, for example, at least one T flip-flop circuit. In contrast to conventional digital frequency dividers, the division ratio may thus be 1:n if n≠2ⁱ for i being a natural number greater than zero. For the purposes of the present disclosure, this is also referred to as a non-binary division ratio, as opposed to binary division ratios, which are a division of a power of 2. Exemplary embodiments therefore also permit uneven division factors (for example 1/7 or ⅕ or 1/9).

Optionally, the first coupling circuit comprises for each division signal a (separate) input with a diode each. The diodes are arranged in such a way as to suppress a signal flow into the counting unit (and thus to prevent an interaction between the outputs of the counting unit) and to superimpose the division signals from the counting unit at an output of the first coupling circuit to form the coupling signal. For example, the first coupling circuit may have only a single output that is connected to the outputs of the diodes (downstream of the signal flow). In other words, the corresponding signal lines can be electrically connected to one another at the output so that the signals overlap and the corresponding coupling signal is formed. Optionally, it would also be possible for the first coupling circuit to be formed by at least one AND gate with a plurality of inputs. It goes without saying that the simple realization with diodes offers the advantage over the AND gate that the circuit can be realized by simple means on a printed circuit board. An AND gate would be a much more complex circuit.

Optionally, the first coupling circuit comprises at least one switch between a respective diode and the associated input of the first coupling circuit in order to decouple the respective diode in response to a control signal (for example from a controller) and thus generate a coupling signal with a different division ratio. The outputs can be activated/deactivated in this way and the division ratio is changed as a result. Optionally, however, also no switches are provided in order to implement a fixed division ratio. Neither the switches nor the diodes are mandatory (an AND gate could also be provided instead).

Optionally, the second coupling circuit comprises a delay circuit which is designed to enter the coupling signal from the first coupling circuit into the reset input of the counting unit with a time delay. Interference can be avoided in this way if, for example, a signal clock cycle has not yet properly finished, but the counting unit is already reset by a HIGH at the reset input. As a result of the delay circuit, the HIGH level is thus formed for long enough in the coupling signal. The delay circuit can be formed, for example, by an RC element.

Optionally, the second coupling circuit comprises a resistor and a connection to a supply voltage (which provides a HIGH level). This achieves the technical effect that the counter is reset in the basic state, which is achieved by the HIGH level.

Optionally, the digital frequency divider comprises an additional counting unit which has a clock input for a clock signal, a reset input for a reset signal, and a plurality of outputs for additional division signals. The second coupling circuit may then be designed to input the coupling signal into the clock input of the additional counting unit (that is to say there is a corresponding electrical connection). The reset input of the additional counting unit can be connected to a ground connection, GND. The plurality of outputs of the additional counting unit can be provided as output signals for the voltage supply circuit and/or for the controller. This offers an advantage that the controller can also receive feedback about the current frequency division (for example for a test mode). The output signals can therefore be used for various purposes.

Exemplary embodiments also refer to a voltage supply circuit for a controller of a vehicle. The voltage supply circuit comprises a power management system for providing a voltage for the controller and a digital frequency divider described above. The digital frequency divider is designed to receive a clock signal from the controller and to divide the received clock signal in a predetermined division ratio and to provide (transmit) an output (output signal) to the power management system.

The vehicle may be a commercial vehicle (for example a truck or bus). The power management system may be a highly integrated power management IC (PMIC). The power management system can provide battery charging, voltage conversion (for example AC/DC or DC/DC), analog-to-digital conversion (ADC), voltage scaling, and other functions such as monitoring, sequencing, and functional safety support.

Optionally, the power management system is designed to authenticate the controller based on the output or the output signal. For example, it is possible to check whether a frequency of the output is in a predetermined acceptance window. The digital frequency divider may thus be part of a monitoring circuit (for example a so-called watchdog) which ensures that the controller and the voltage supply are compatible with one another or that the controller has been configured correctly. Only then can the controller be connected to the voltage supply. It is therefore possible that the voltage supply or the corresponding chip and the controller can originate from different manufacturers without this affecting the operation of the entire system.

Optionally, the clock signal includes a frequency f0 between 10 kHz and 50 kHz or approximately 25 or 28 kHz. The predetermined division ratio may be 1:n, where n may be an integer between 6 and 32 or more. The invention is not intended to be restricted to certain values. The specific values are only used as example values. For example, if the digital frequency divider has two counting units, an example frequency division of 1:28 (28=7×4) can be implemented. Given an example clock frequency of 25 kHz, it is possible to select an acceptance window of 0.75 . . . 1 kHz, with this still containing tolerance variations. If no expected signal is received in this example acceptance window, it is possible to issue a warning or error message, which puts the system in a safe state.

Exemplary embodiments also refer to a controller of a vehicle which comprises the following: a connection for a previously described voltage supply circuit and an output for a clock signal at a predetermined frequency f0 for a previously described digital frequency divider. The controller is designed to control the digital frequency divider.

Optionally, the controller comprises a controller input for an output of the digital frequency divider and optionally at least one control output for actuating the at least one switch, as has been described as part of the frequency divider. The controller may then be designed to trigger a test mode in which the controller causes at least one of the following:
changing the predetermined frequency f0 of the clock signal and verifying an expected change at the controller input;
optionally decoupling one or more diodes by activating the corresponding switch (to switch off at least one diode) and verifying an expected change at the controller input.

For example, the controller can receive a predetermined frequency signal (=signal at predetermined frequency) via an output of the additional counting unit and compare it with a reference value. This enables monitoring to be implemented in order to ensure correct operation. The controller can thus switch the switches in the first coupling circuit of the digital frequency divider in order to selectively change a frequency ratio and, in response to the received frequency signal, to determine whether the voltage supply is functioning as expected (that is to say according to the changed frequency division).

Exemplary embodiments also refer to a commercial vehicle (for example a truck or a bus) having a previously described controller and a previously described voltage supply circuit.

Exemplary embodiments also refer to a method for operating and testing a voltage supply circuit having the following steps:
providing a voltage for a vehicle controller;
transmitting, by way of the vehicle controller, a clock signal at a predetermined frequency f0;
dividing the frequency f0 of the clock signal by a non-binary division ratio; and
authenticating the vehicle controller when the divided frequency is in a predetermined acceptance window.

As already mentioned, for the purposes of the present disclosure, a non-binary division ratio is a division ratio of 1:n for each n that is not a power of 2.

Optionally, the method comprises forwarding a divided frequency signal to a controller input of the vehicle controller. The method may also comprise testing the voltage supply, wherein the testing comprises at least one of the following steps:
changing the predetermined frequency of the clock signal and verifying an expected change at the controller input;
changing the non-binary division ratio and verifying an expected change at the controller input.

As already explained, the frequency ratio can be changed by optionally decoupling one or more diodes by activating the corresponding switches. Since this change is known, it can be used for testing.

It is understood that all of the previously described functions of the frequency divider can be designed as further optional method steps. It is also understood that the listing sequence is not necessarily a sequence in which the method steps are performed. The steps may also be performed in another sequence or only some of the method steps are performed.

This method or at least parts of this method may likewise be implemented or stored in the form of instructions in software or on a computer program product, wherein stored instructions are capable of executing the steps according to the method when the method runs on a processor. Therefore, the present invention likewise relates to a computer program product having software code (software instructions) stored thereon that is designed to execute one of the methods described above when the software code is executed by a processing unit. The processing unit may be any form of computer or control unit that has a corresponding microprocessor that is able to execute a software code. In addition, exemplary embodiments refer to a computer-readable storage medium with instructions stored thereon, which are designed to cause the voltage supply circuit described above and the controller described above to carry out the method when the instructions are carried out on a data processing unit.

Exemplary embodiments offer the advantage that an incompatibility between the microcontroller and the voltage supply can be detected immediately, since the frequency provided by the microcontroller is most likely outside the acceptance window, which according to exemplary embodiments is freely adjustable over a large range. A disadvantage of conventional monitoring units is specifically that the acceptance window can be selected in only limited fashion or with regard to two certain powers of the clock frequency entered. According to exemplary embodiments, however, any uneven division factors can be realized, which provide significantly more options for providing a sufficiently narrow acceptance window. For example, the acceptance window may be between 0.75 kHz and 1 kHz if the typical clock frequency is 25 or 28 kHz. In addition, exemplary embodiments have the advantage that test options are provided. For example, the division factor can be dynamically changed by switching diodes on and off via dedicated switches, whereby the change can be used to read whether the monitoring unit or the voltage supply is operating as intended. In addition, different division factors of the clock signal entered can be realized via multiple outputs, whereby these are not only powers of two, but also uneven division factors can be implemented.

From the conscious detuning of the monitoring unit, it is possible to test very quickly and reliably whether the frequency divider or the voltage supply are operating as intended.

The exemplary embodiments of the present invention will be better understood from the following detailed description and the attached drawings of the various exemplary embodiments, which however are not intended to be understood such that they restrict the disclosure to the specific embodiments, but rather serve merely for the purposes of explanation and understanding.

Other objects, advantages and novel features of the present invention will become apparent from the following detailed description of one or more preferred embodiments when considered in conjunction with the accompanying drawings.

### BRIEF DESCRIPTION OF THE DRAWINGS

FIG. 1 shows a digital frequency divider according to one exemplary embodiment of the present invention.

FIG. 2 shows further details of the frequency divider according to further exemplary embodiments.

FIG. 3 illustrates the frequency division of a frequency divider according to further exemplary embodiments.

FIG. 4 illustrates an implementation of a monitoring circuit in a voltage supply for a controller according to exemplary embodiments.

FIG. 5 shows a schematic flowchart for one exemplary embodiment of a method for operating a monitoring circuit.

### DETAILED DESCRIPTION OF THE DRAWINGS

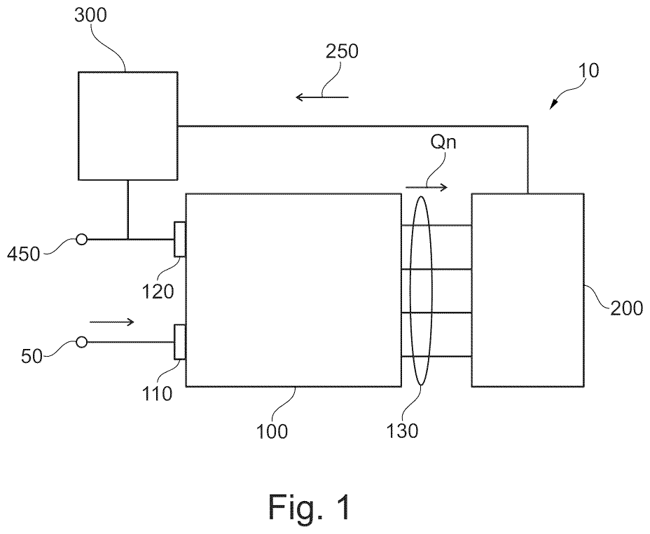

FIG. 1 shows one exemplary embodiment for a digital frequency divider 10. For example, the digital frequency divider 10 can be integrated into a voltage supply that supplies power to a corresponding controller (for example in a vehicle). However, the digital frequency divider 10 can also be formed as a separate component.

The digital frequency divider 10 comprises a counting unit 100. The counting unit 100 comprises a clock input 110 for a clock signal 50, a reset input 120 for a reset signal, and a plurality of outputs 130 for division signals Qn (n=1, 2, 3, 4, . . . ). The counting unit 100 is designed to generate the division signals Qn as a division of the clock signal 50, wherein the division is a power of two. For example, an n-th division signal may have a division frequency of f=f0/2ⁿ, where f0 is the frequency of the clock signal 50 and n may be any natural number.

The digital frequency divider 10 furthermore comprises a first coupling circuit 200 and a second coupling circuit 300. The first coupling circuit 200 is designed to couple the division signals Qn to form a coupling signal 250. The coupling is carried out in such a way that the coupling signal 250 has a logical HIGH (HIGH level) only if all the coupled division signals Qn have a logical HIGH. The level of the HIGH signals may differ, but does not have to. Otherwise, the coupling signal 250 is set to a logical LOW. In other words, if at least one of the division signals Qn has a LOW, the coupling signal 250 is also a LOW signal. The first coupling circuit 200 may be formed, for example, as an AND gate. The second coupling circuit 300 couples the coupling signal 250 to the reset input 120 of the counting unit 100. In the simplest case, the coupling signal 250 can be simply passed through.

The counting unit 100 may be, for example, a digital asynchronous counter or an asynchronous n-bit dual counter, which has multiple output signals Qn, wherein each output signal itself is a clock signal, but at a frequency reduced by a power of 2.

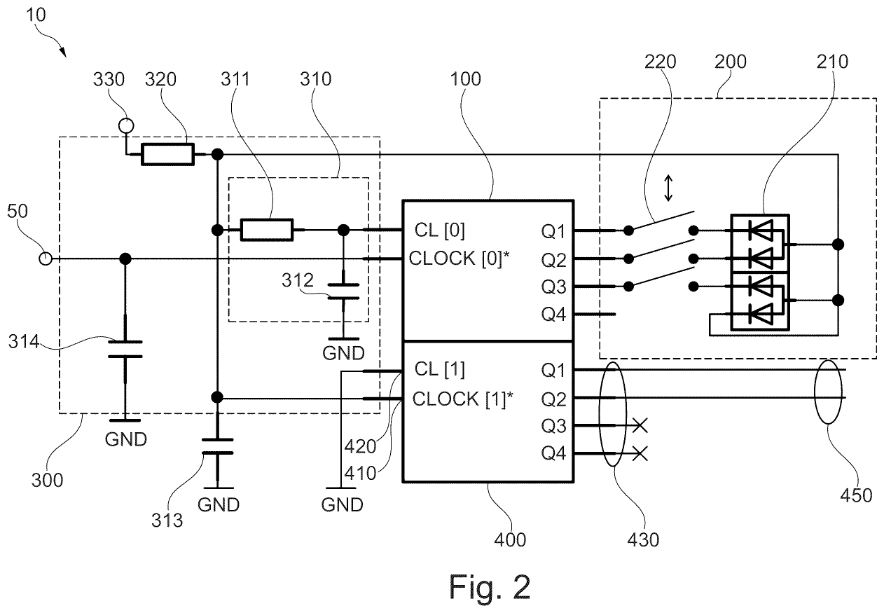

FIG. 2 shows the digital frequency divider, with further optional details, which may be formed according to further exemplary embodiments.

The first coupling circuit 200 thus comprises, for each division signal Qn, an input and a respective diode 210. The diodes 210 are interconnected or formed so as to suppress a signal flow into the counting unit 100 and to superimpose the division signals Qn at an output of the first coupling circuit 200 to form the coupling signal 250. The corresponding signal cables from the diodes 210 can simply be electrically connected to one another.

According to the exemplary embodiment shown, the first coupling circuit 200 may have at least one switch 220 between a respective diode 210 and the respective input of the first coupling circuit 200. Alternatively, the switch/switches 220 could also be arranged downstream of the respective diode 210 along the signal flow. In any case, the switch or switches 220 cause(s) signals to be decoupled from the coupling signal 250 by way of the respective diode(s) 210. This in turn results in a different division ratio. In particular, however, an associated switch 220 may also be provided for each diode 210. The one or more switches 220 can be actuated individually (for example by way of the controller or another control unit) in order to test the circuit or to be able to flexibly adjust the division factor (division ratio).

According to the exemplary embodiment shown, the second coupling circuit 300 may have a delay circuit 310. The delay circuit 310 is designed to enter the coupling signal 250 from the first coupling circuit 200 into the reset input 120 of the counting unit 100 with a time delay. For example, the delay circuit 310 may have an RC member, wherein the coupling signal 250 is passed through a first resistor 311 and the line between the first resistor 311 and the reset input 120 is connected via a capacitor 312 to ground GND.

According to the exemplary embodiment shown, the second coupling circuit 300 may have a second resistor 320 and a connection 330 for a supply voltage. This ensures that the counting unit 100 is reset in the basic state (reset state), so that the counting unit 100 only begins to count if the coupling signal 250 returns a LOW state.

According to the exemplary embodiment shown, the digital frequency divider 10 may have an additional counting unit 400. The additional counting unit 400 comprises a clock input 410 for a clock signal, a reset input 420 for a reset signal, and a plurality of outputs 430 for additional division signals. For example, it may be of identical design to the counting unit 100, but the additional counting unit 400 can be interconnected differently. Thus, according to the exemplary embodiment shown, the second coupling circuit 300 is connected to the clock input 410 of the additional counting unit 400 in order to use the coupling signal 250 as the clock signal for the second counting unit 400. In addition, the reset input 420 of the additional counting unit 400 can be connected to a ground connection GND. The outputs 430 of the additional counting unit 400 can be used to provide various division frequencies as output signals 450 for other components (for example for the voltage supply and/or the controller). Two of the outputs 430 are unused in the exemplary embodiment shown (the lower two), but can optionally also be used as the output 450 in order to realize other division ratios. For example, the controller can selectively query signals from one of the outputs 450 in order to test the frequency divider 10 (for example by comparison with an expected frequency).

According to the exemplary embodiment shown, the digital frequency divider 10 can have filter units, for example in order to filter out high-frequency interference signals. For example, a second capacitor 313 can be formed as a low-pass filter for the coupling signal 250, that is to say high-frequency signal components of the coupling signal 250 are discharged to ground GND. An additional low-pass filter can optionally be formed at an input for the clock signal 50 as a fourth capacitor 314.

According to exemplary embodiments, the clock signal 50 may have a value between 10 kHz and 100 kHz or approximately 25 kHz or approximately 28 kHz. In addition, a frequency f in an output signal 450 may have a division ratio of 1:28 or 1:56 (i.e. f=f0/28, f0/56) in comparison to the clock signal 50. At a clock frequency of 25 kHz, this therefore results in a frequency of approximately 0.9 kHz or approximately 450 Hz. The acceptance window for the monitoring circuit can therefore be selected for the frequency range between 0.75 . . . 1 kHz. It goes without saying that the values are merely examples, and exemplary embodiments should not be restricted to these specific values.

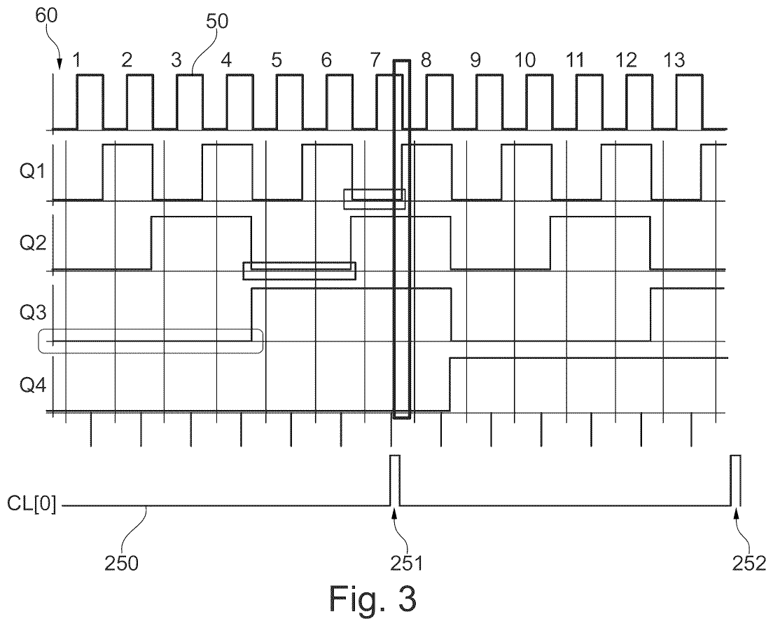

FIG. 3 illustrates the mode of operation of the digital frequency counter 10 from FIG. 2. Firstly, the top of FIG. 3 shows the clock signal 50 at a predetermined frequency f0. In addition, the first division signal Q1 is shown below this. The first division signal Q1 is also a clock signal, but at only half the clock frequency f0/2 compared to clock signal 50. Furthermore, the second division signal Q2 is shown below this, which is also a clock signal at a clock frequency of ¼ of the frequency f0 of the clock signal 50. In addition, the third division signal Q3 is shown below this, which has a clock frequency of ⅛ of the frequency of the clock signal 50. Thus, the division frequencies of the division signals Q1, Q2 and Q3 are reduced by a factor of ½i (i=1, 2, 3) (with respect to clock signal 50). Optionally, a fourth division signal Q4 may also be provided, which has a clock frequency of 1/16 in comparison to the clock signal 50. These division signals Q1, Q2, Q3, Q4 are output by the counting unit 100.

At the beginning, the basic state 60 is shown, which is present, for example, if no clock signal 50 is entered. In the basic state 60, all outputs are at a LOW level and the state is ensured by the connection and the voltage supply via the connection 330.

The very bottom of FIG. 3 shows the resulting coupling signal 250. According to exemplary embodiments, the coupling is carried out in such a way that the coupling signal 250 is basically at LOW as long as at least one of the three division signals Q1, Q2 or Q3 is at LOW. Exemplary embodiments achieve this by virtue of the outputs of the diodes 210 being electrically connected to one another downstream of the signal flow. The coupling signal 250 therefore only jumps to a logical HIGH 251, 252 if all are at HIGH level, that is to say when the seventh clock cycle of the clock signal 50 ends.

Since the coupling signal 250 is returned to the reset input 120 of the counting unit 100, the counting unit 100 is reset at this moment. This causes the counting unit 100 to be set to the basic state 60, which was applied before the first clock cycle of the clock signal 50. The procedure is then repeated so that, with the end of the 7th clock cycle, the coupling signal 250 also has the state HIGH again (see pulses 251 and 252).

The coupling of the division signals Q1, Q2, Q3 shown results in the coupling signal 250 having a division frequency of 1/7*f0, that is to say 7 clock cycles are initially waited before the coupling signal 250 has the first HIGH signal. Until then, the coupling signal 250 was constantly at LOW.

It is understood that, if individual diodes 210 of the first coupling circuit 200 are switched off, the corresponding division signals Q1 or Q2 or Q3 are not present. For example, the absence of the division signal Q2 results in the coupling signal 250 assuming the first HIGH state after the fifth clock cycle, that is to say the division ratio is ⅕. Switching off the first diode 210 and accordingly the first division signal Q1 results in the first HIGH signal in the coupling signal 250 being reached after 6 clock cycles (division frequency would be ⅙*f0). Finally, switching off the third diode and thus the third division signal Q3 results in the first HIGH signal in the coupling signal 250 being reached after three clock cycles (division frequency would be ⅓*f0). Many division ratios can thus be achieved by switching on and off the corresponding diodes or the corresponding division signals Q1, Q2, Q3. Additional division factors can be implemented (for example from ½ to 1/15) by way of the optional connection of the fourth division signal Q4.

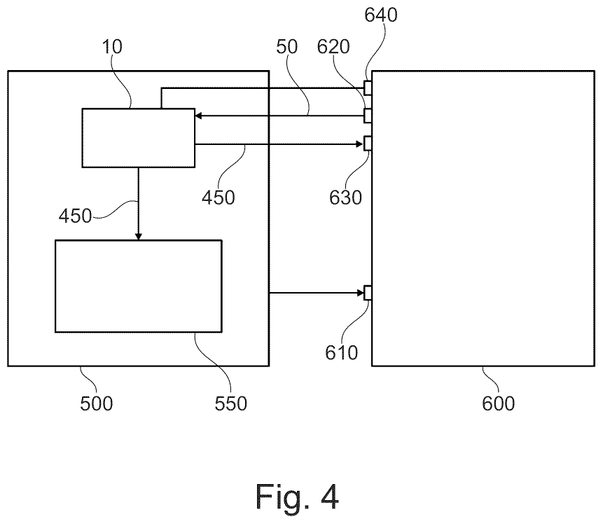

FIG. 4 shows an exemplary embodiment of a voltage supply circuit 500 for a controller 600, wherein the voltage supply circuit 500 has a previously described digital frequency divider 10 used for a monitoring circuit (watchdog circuit) or is a part thereof. The monitoring circuit can ensure that the controller 600 is functioning as expected. The controller 600 may be any vehicle controller which provides a predetermined function in the vehicle (for example in a truck). The predetermined functions may be, for example, steering, braking, gear shifting and more. In particular, the controller 600 may be a microcontroller.

In addition, the voltage supply circuit 500 may comprise a power management system 550 which may comprise, for example, a voltage supply chip. The power management system 550 may be, for example, a highly integrated power management circuit (PMIC) which, for example, can provide charging of batteries, voltage conversion (AC voltage to DC voltage, DC, or DC/DC), analog-to-digital conversion (ADC), voltage scaling, monitoring, sequencing, and other functional security support. The voltage supply circuit 500 is thus at least used to supply voltage for the controller 600 which has a supply connection 610 for this purpose.

According to exemplary embodiments, the controller 600 transmits a frequency signal (for example the clock signal 50) via the output 620 (clock signal output) to the digital frequency divider 10. The frequency divider 10 is set to a predetermined division frequency 1:n and the output 450 has a frequency f=f0/n, where n may be any natural number. In particular, n is a non-binary number (that is to say is not a power of 2), but can be freely selected according to exemplary embodiments.

According to exemplary embodiments, the monitoring circuit checks whether the frequency f of the output signal 450 is in an acceptance window (=frequency range of predetermined size). If this is the case, the voltage supply circuit 500 can authenticate the controller 600 accordingly. If this is not the case, an appropriate warning can be issued or the voltage supply circuit 500 can interrupt the voltage supply because the corresponding controller 600 appears to be incompatible.

According to exemplary embodiments, the controller 600 can test the frequency divider 10 or the voltage supply circuit 500. For this purpose, the controller 600 may have a connection via a signal input 630 (controller input) to an output 450 of the digital frequency divider 10 in order to receive at least one output signal 450. During testing (test mode), the controller 600 can detune the clock frequency f0 of the clock signal 50 via the clock signal output 620, for example to output only 15 kHz or 30 kHz instead of 25 kHz. If the division ratio remains the same during testing, the frequency f of the received output signal 450 will change. From the change, the controller 600 can conclude whether the frequency divider 10 is operating as expected.

In addition, the controller 600 can use a corresponding control output 640 to actuate control lines which are connected to one or to multiple or to all switches 220 of the first coupling circuit 200 in order to selectively change the division ratio of the frequency divider 10. Here, too, there will be an expected change in the frequency f in the output signal 450 and the controller 600 can conclude from this whether the frequency divider 10 or the monitoring circuit are functioning as desired. Exemplary embodiments thus enable the frequency divider 10 to be monitored by the controller 600.

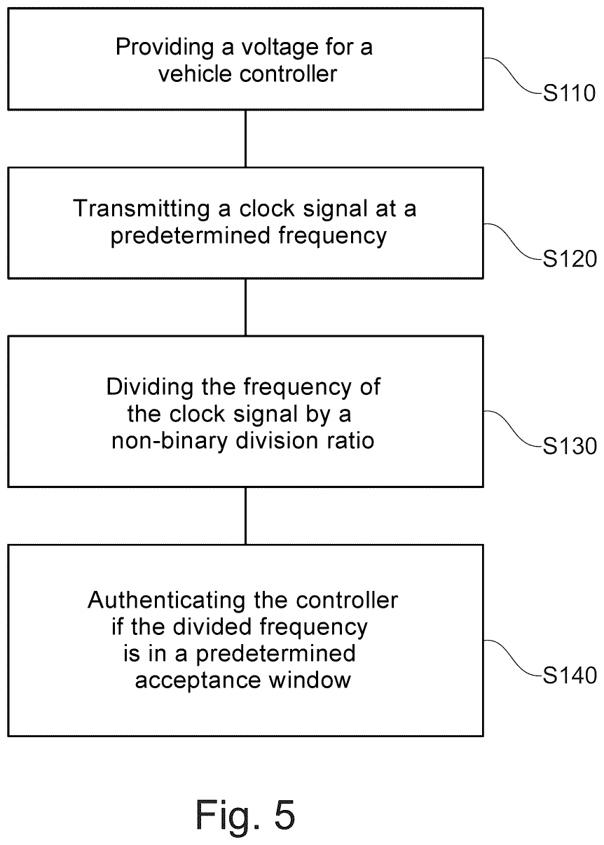

FIG. 5 shows a schematic flowchart for one exemplary embodiment of a method for operating a monitoring circuit which is housed, for example, in the voltage supply circuit 500. The method comprises:
providing S110 a voltage for a vehicle controller 600;
transmitting S120, by way of the vehicle controller 600, a clock signal 50 at a predetermined frequency f0;
dividing S130 the frequency f0 of the clock signal 50 by a non-binary division ratio; and
authenticating S140 the vehicle controller 600 when the divided frequency f is in a predetermined acceptance window.

The method may also comprise the following steps:
changing the predetermined frequency of the clock signal 50 and verifying an expected change at the controller input 630; and/or
changing the non-binary division ratio (by switching the switches 220) and verifying an expected change at the controller input 630.

It is understood that all of the previously described functions of the evaluation circuit can be designed as further optional method steps. It is also understood that the listing sequence does not necessarily imply a sequence in which the method steps are performed. The steps may also be performed in another sequence or only some of the method steps are performed.

The method may likewise be computer-implemented, i.e. it may be implemented through instructions which are stored on a storage medium and are capable of executing the steps of the method when it runs on a processor. The instructions typically comprise one or more instructions which are able to be stored in various ways on various media in or peripherally with respect to a control unit (having a processor) which, when they are read and executed by the control unit, prompt the control unit to execute functions, functionalities and operations that are necessary for performing a method according to the present invention.

The description and the drawings illustrate only the principles of the disclosure. A person skilled in the art will therefore be able to develop various arrangements which, although not expressly described or shown herein, embody the principles of the disclosure and fall within its scope of application.

The functions of various elements shown in the figures, including all function blocks, referred to as “coupling circuits”, “delay device”, “counting units”, etc. can be provided through the use of specific hardware, such as “signal generator”, “signal processing unit”, “processor”, “control unit”, etc. and through hardware that is capable of running software in conjunction with appropriate software. In addition, any unit referred to herein as “device” may correspond to or be implemented as “one or more modules”, “one or more devices”, “one or more units”, etc. When the functions are provided by a processor, they can be provided by a single dedicated processor, by a single shared processor, or by a plurality of individual processors, some of which can be shared. In addition, the explicit use of the term “processor” or “controller” should not be understood as referring solely to hardware capable of running software, and it may implicitly and without limitation include digital signal processor hardware (DSP), network processors, application-specific integrated circuits (ASIC), field-programmable gate arrays (FPGA), read-only memories (ROM) for storing software, random access memories (RAM), and non-volatile memories. Other hardware, conventional and/or custom, may also be included.

Those skilled in the art should know that all block diagrams included herein represent conceptual views of circuits that embody the principles of the disclosure. Similarly, it is recognized that all flowcharts, state transition diagrams, pseudocodes and the like represent different processes that are substantially represented in a computer-readable medium and can thus be executed by a computer or processor, regardless of whether such a computer or processor is explicitly represented or not.

In addition, the following claims are hereby incorporated into the detailed description, where each claim may stand alone as a separate example. While each claim may stand alone as a separate example, it is important to note that, although a dependent claim in the claims may relate to a specific combination with one or more other claims, other examples may also include a combination of the dependent claim with the subject matter of any other dependent or independent claim. Such combinations are proposed here, unless it is stated that a particular combination is not intended. In addition, the intention is to also include features of a claim in another independent claim, even if that claim is not made directly dependent on the independent claim.

It should also be noted that the methods disclosed in the description or in the claims may be implemented by a device comprising means for carrying out each of the respective actions of those methods. It should also be understood that the disclosure of multiple actions or functions disclosed in the description or claims cannot be interpreted as being in a particular order. Therefore, the disclosure of multiple actions or functions does not limit them to a specific order, unless such actions or functions are not interchangeable for technical reasons. Furthermore, in some examples, a single action may include multiple sub-actions or may be subdivided into multiple sub-actions. Such sub-actions may be included in the disclosure of this individual action, unless expressly excluded.

Furthermore, although each embodiment may stand alone, it should be noted that, in other embodiments, the defined features can be combined differently, that is to say a certain feature described in one embodiment can also be realized in other embodiments. Such combinations are covered by the present disclosure, unless it is stated that a particular combination is not intended.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

### LIST OF REFERENCE SIGNS

10 (Digital) frequency divider
50 Clock signal
60 Basic state
100, 400 Counting unit(s)
110, 410 Clock input
120, 420 Reset input
130, 430 Outputs
200 First coupling circuit
210 Diode(s)
220 (Multiple) switches
250 Coupling signal
300 Second coupling circuit
310 Delay circuit
311, 312 RC element
313, 314 Low-pass filter
320 Resistor
330 Voltage connection
450 Output, output signal(s)
500 Voltage supply circuit
550 Power management system
600 Controller
610 Connection for voltage supply
620 Output of a clock signal
630 Controller input for an output of the frequency divider
640 At least one control output for the switch/switches
f0 Frequency of the clock signal
Qn Division signals
GND Ground

What is claimed is:

1. A digital frequency divider for a voltage supply circuit of a controller, the digital frequency divider comprising:
a counting unit which has a clock input for a clock signal, a reset input for a reset signal, and a plurality of outputs for division signals, the counting unit being configured to generate the division signals as a division of the clock signal by a power of 2;
a first coupling circuit for coupling the division signals to form a coupling signal, wherein the coupling signal has a logical HIGH only when all coupled division signals have a logical HIGH; and
a second coupling circuit which is designed to enter the coupling signal into the reset input of the counting unit.

2. The digital frequency divider according to claim 1, wherein
the first coupling circuit has, for each division signal, an input with a respective diode and,
the diodes are arranged so as to suppress a signal flow into the counting unit and to superimpose the division signals from the counting unit at an output of the first coupling circuit to form the coupling signal.

3. The digital frequency divider according to claim 2, wherein
the first coupling circuit has at least one switch between a respective diode and its respective input of the first coupling circuit so as to decouple the respective diode in response to a control signal and thus generate a coupling signal with a different division ratio.

4. The digital frequency divider according to claim 1, wherein
the second coupling circuit has a delay circuit which is designed to enter the coupling signal from the first coupling circuit into the reset input of the counting unit with a time delay.

5. The digital frequency divider according to claim 4, wherein
the second coupling circuit has a resistor and a connection to a supply voltage.

6. The digital frequency divider according to claim 1, further comprising:
an additional counting unit which has a clock input for a clock signal, a reset input for a reset signal, and a plurality of outputs for additional division signals,
wherein the second coupling circuit is designed to enter the coupling signal into the clock input of the additional counting unit and the reset input of the additional counting unit is connected to a ground connection, and
wherein the plurality of outputs of the additional counting unit provide output signals for the voltage supply circuit and/or for the controller.

7. A voltage supply circuit for a controller of a vehicle, the voltage supply circuit comprising:
a power management system for providing a voltage for the controller; and
a digital frequency divider according to claim 1,
wherein the digital frequency divider is configured to receive the clock signal from the controller and to divide the received clock signal in a predetermined division ratio and to provide an output to the power management system.

8. The voltage supply circuit according to claim 7, wherein
the power management system is designed to authenticate the controller based on the output when the output has a frequency which is in a predetermined acceptance window.

9. The voltage supply circuit according to claim 8, wherein
the clock signal has a frequency, f0, between 10 kHz and 100 kHz and the predetermined division ratio is 1:n, wherein n is an integer between 16 and 32.

10. The voltage supply circuit according to claim 9, wherein
the frequency, f0, is approximately 25 kHz or approximately 28 kHz.

11. A controller of a vehicle, comprising:
a connection for a voltage supply circuit,
an output for a clock signal at a predetermined frequency, f0, for a digital frequency divider;
wherein the controller is designed to control the digital frequency divider,
wherein the digital frequency divider comprises:
a counting unit which has a clock input for the clock signal, a reset input for a reset signal, and a plurality of outputs for division signals, the counting unit being configured to generate the division signals as a division of the clock signal by a power of 2;
a first coupling circuit for coupling the division signals to form a coupling signal, wherein the coupling signal has a logical HIGH only when all coupled division signals have a logical HIGH; and
a second coupling circuit which is designed to enter the coupling signal into the reset input of the counting unit; and
wherein the voltage supply circuit comprises:
a power management system for providing a voltage for the controller,
wherein the digital frequency divider is configured to receive the clock signal from the controller and to divide the received clock signal in a predetermined division ratio and to provide an output to the power management system.

12. The controller according to claim 11, further comprising:
a controller input for an output of the digital frequency divider, wherein the digital frequency divider includes the first coupling circuit having at least one switch between a respective diode and its respective input of the first coupling circuit so as to decouple the respective diode in response to a control signal and thus generate a coupling signal with a different division ratio, and
a control output for actuating the at least one switch,
wherein the controller is designed to trigger a test mode in which the controller causes at least one of the following:
changing the predetermined frequency, f0, of the clock signal and verifying an expected change at the controller input;
optionally decoupling one or more diodes by activating the corresponding switch and verifying an expected change at the controller input.

13. A commercial vehicle comprising a controller according to claim 11.

14. A method for operating and testing a voltage supply circuit, comprising:
providing a voltage for a vehicle controller;
transmitting, by way of the vehicle controller, a clock signal at a predetermined frequency f0;
dividing the frequency f0 of the clock signal by a non-binary division ratio; and
authenticating the vehicle controller when the divided frequency is in a predetermined acceptance window.

15. The method according to claim 14 wherein a divided frequency f is forwarded to a controller input of the vehicle controller, the method further comprising:
testing the voltage supply circuit, wherein the testing comprises at least one of the following steps:
changing the predetermined frequency f0 of the clock signal and verifying an expected change at the controller input;
changing the non-binary division ratio and verifying an expected change at the controller input.
